(19) United States
(12) Patent Application Publication
(10) Pub. No.: US 2025/0255034 A1
(43) Pub. Date: Aug. 7, 2025

(54) PHOTODIODE WITH CONTROLLED DIFFRACTION

(71) Applicant: SEMICONDUCTOR COMPONENTS INDUSTRIES, LLC, Scottsdale, AZ (US)

(72) Inventor: Byounghee LEE, Boise, ID (US)

(73) Assignee: SEMICONDUCTOR COMPONENTS INDUSTRIES, LLC, Scottsdale, AZ (US)

(21) Appl. No.: 18/430,874

(22) Filed: Feb. 2, 2024

(51) Int. Cl. H01L 31/0232; H01L 31/107; H01L 31/18; H04N 23/16

(52) U.S. Cl. CPC H10F 77/413; H04N 23/16; H10F 30/225; H10F 71/121

(57) ABSTRACT

An image sensor pixel is disclosed. The sensor pixel includes a photodiode and a diffraction structure. The photodiode includes an avalanche region, and may generate an initial charge carrier using a particular photon received on a first side of the photodiode, and generate an avalanche current in response to a generation, by the initial charge carrier via impact ionization, of multiple additional charge carriers in the avalanche region. The diffraction structure is coupled to a second side of the photodiode opposite the first side, and is configured to reflect a given photon that has passed through the photodiode without generating a corresponding charge carrier, back into the avalanche region.

### BACKGROUND

### Technical Field

This disclosure is related to sensors and, more particularly, to silicon photomultiplier (SiPM) and single-photon avalanche diode (SPAD) image sensors.

### Description of the Related Art

In many computer and mechanical systems, a variety of sensors may be employed to detect different environmental and operational conditions, and generate analog or digital signals corresponding to the detected conditions. In some systems, temperature sensors may be employed to detect the temperature of a system in order to determine if the system is operating in a specified temperature range. Other systems may employ accelerometer sensors to aid in the determination of movement of the system or part of the system. In robotic systems, rotational sensors may be used to determine how far a portion of a system, for example, a robotic arm, has rotated. In imaging or camera systems, SiPM and SPAD image sensors may be used to capture image data from exposed light or other forms of electromagnetic radiation.

### SUMMARY

Various embodiments of a sensor pixel for an image sensor are disclosed. Broadly speaking, a sensor pixel includes a photodiode and a diffraction structure. The photodiode includes an avalanche initiation region and may be configured to generate an initial charge carrier using a particular photon of a plurality of photons received on a first side of the photodiode. The photodiode may be further configured to generate an avalanche current in response to a generation, by the initial charge carrier via impact ionization, of a plurality of additional charge carriers in the avalanche region. The diffraction structure may be coupled to a second side of the photodiode opposite the first side, and may include a plurality of first metal lines. The diffraction structure may be configured to reflect at least one of the plurality of photons back into the avalanche initiation region.

### BRIEF DESCRIPTION OF THE DRAWINGS

For a detailed description of example embodiments, reference will now be made to the accompanying drawings in which:

FIG. 1 is a cross-section diagram of an embodiment of an image sensor pixel that includes a photodiode.

FIG. 2 is a block diagram of an embodiment of a periodic diffraction structure.

FIG. 3 is a block diagram of an embodiment of a non-periodic diffraction structure.

FIG. 4 is a cross-section diagram of an embodiment of a sensor pixel.

FIG. 5 is a block diagram of an embodiment of a multi-layer diffraction structure.

FIG. 6A is a block diagram of an embodiment of a diffraction structure that includes multiple islands of metal or any other suitable dielectric material.

FIG. 6B is a block diagram of an embodiment of a diffraction structure that includes a plane of metal or any other suitable dielectric material that has multiple holes.

FIG. 7 is a block diagram of an embodiment of an image sensor.

FIG. 8 is a block diagram of an embodiment of an imaging system.

FIG. 9 is a block diagram of an embodiment of a vehicle with an incorporated imaging system.

FIG. 10 is a flow diagram of an embodiment of a method for operating a sensor pixel in an image system.

Many of the electrical connections in the drawings are shown as direct couplings having no intervening devices, but are not expressly stated as such in the following description. Nevertheless, this paragraph shall serve as antecedent basis in the claims for referencing any electrical connection as “directly coupled” for electrical connections shown in the drawing with no intervening device(s).

### Definitions

Various terms are used to refer to particular system components. Different companies may refer to a component by different names—this document does not intend to distinguish between components that differ in name but not function. In the following discussion and in the claims, the terms “including” and “comprising” are used in an open-ended fashion and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

“A,” “an,” and “the,” as used herein, refers to both singular and plural referents unless the context clearly dictates otherwise. By way of example, “a processor” program med to perform various functions refers to one processor programmed to perform each and every function, or more than one processor collectively programmed to perform each of the various functions.

In relation to electrical devices (whether stand alone or as part of an integrated circuit), the terms “input” and “output” refer to electrical connections to the electrical devices, and shall not be read as verbs requiring action. For example, a differential amplifier (such as an operational amplifier) may have a first differential input and a second differential input, and these “inputs” define electrical connections to the operational amplifier, and shall not be read to require inputting signals to the operational amplifier.

“Controller” or “controller circuit” shall mean, alone or in combination, individual circuit components, an application specific integrated circuit (ASIC), a microcontroller with controlling software, a reduced-instruction-set computing (RISC) circuit with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

Various sensor circuits may be used in a variety of computer, mechanical, electro-mechanical, and imaging systems. Such sensor circuits determine and relay environmental and/or operational information that can be used as part of a control mechanism. For example, to perform lane-keeping assist, collision warning, distance-pacing cruise-control systems, autonomous driving systems, proximity detection, and the like in vehicles, multiple image sensors may be employed.

Some image sensors employ silicon photomultipliers (SiPMs) and/or single-photon avalanche diodes (SPADs) to convert incident light into current signals that can be translated into digital data for processing. Current trends in such image sensors are for reduced sensor pixel pitch, lower operation voltages, higher photon detection efficiency, and faster recovery times.

Decreasing the size of sensor pixels for SiPMs and SPADs can result in lower photo detection efficiency due to the relative size increment of inactive guard-ring regions in the sensor pixels. Such guard-ring structures help prevent early edge breakdown, but reduce the size of the active avalanche initiation probability region (or simply the “avalanche initiation region”). Other areas of a sensor pixel, for example, guard-ring regions, do not contribute to the photon detection efficiency of a sensor pixel.

In some cases, the photon detection efficiency of a sensor pixel in the near infrared range can be enhanced through the use of light scattering structures, for example, a pyramidal array, that increases the absorption path length of the near infrared light. Such conventional light scattering structures, for example, pyramid structures, trench array structures, and the like, merely spread incident light causing at least some of the incident light to be absorbed by inactive regions in a sensor pixel.

The embodiments described herein may provide techniques for using a diffraction structure to spread incident light over an avalanche region of a sensor pixel while avoiding inactive regions of the sensor pixel. Using such a diffraction structure enables more effective spreading of incident light, thereby improving the photon detection efficiency of the sensor pixel, which improves the overall efficiency of an image sensor.

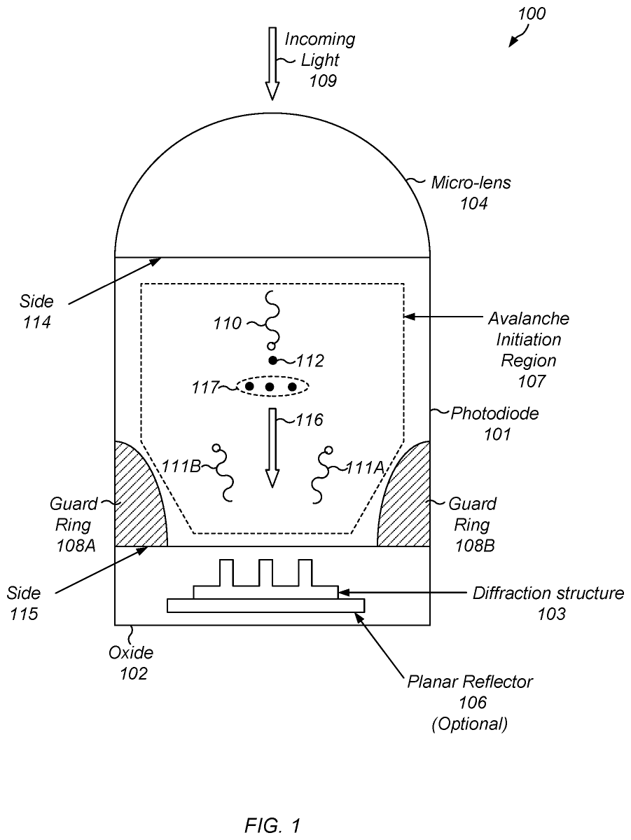

A cross-section diagram of a sensor pixel for an imaging system is depicted in FIG. 1. In various embodiments, sensor pixel 100 may be a SiPM pixel or a SPAD pixel. As illustrated, sensor pixel 100 includes photodiode 101, micro-lens 104, and oxide 102. In various embodiments, photodiode 101 includes avalanche initiation region 107, guard ring 108A, and guard ring 108B, while oxide 102 includes diffraction structure 103 and optional planar reflector 106.

Micro-lens 104 (also referred to as a “lenslet”) is configured to focus incoming light 109 on side 114 of photodiode 101. Micro-lens 104 can be implemented as a single lens or as an array of lenslets with different shapes and sizes. In various embodiments, incoming light 109 may be any suitable frequency of electromagnetic radiation. For example, incoming light 109 may be in the near infrared range or in the visible range when silicon has been used for photodiode 101 material. In various embodiments, micro-lens 104 may be implemented using glass, polymer, or any other material with a suitable index of refraction at the desired frequency of electromagnetic radiation.

Photodiode 101 is configured to generate charge carrier 112 using photon 110 from incoming light 109 which is received on side 114 of photodiode 101. Photodiode 101 is further configured to generate avalanche current 116 in response to a generation, by the initial charge carrier via impact ionization, of a plurality of additional charge carriers 117.

Diffraction structure 103 is adjacent to side 115 of photodiode 101. In various embodiments, side 115 is opposite side 114 of photodiode 101. As described below, diffraction structure 103 includes a plurality of metal structures including lines, islands, holes with arbitrary shapes and sizes and is configured to reflect photons 111A and 111B back into avalanche initiation region 107. In addition to or alternatively to metal, any dielectric material that has different refractive index than the layer surrounding the diffraction structure (for example oxide layer) may be used in the diffraction structure. By reflecting photons 111A and 111B back into avalanche initiation region 107, photons 111A and 111B have a greater chance to generate a charge carrier that can trigger avalanche current 116, thereby improving the photo detection efficiency of sensor pixel 100.

In various embodiments, diffraction structure 103 functions as an optical grating that diffracts incident light into multiple beams traveling in different directions. By adjusting the spacing between and shape of metal structures and/or dielectric material structures included in diffraction structure 103, the direction of the diffracted light can be controlled. In various embodiments, the shapes included in diffraction structure 103 may include lines, islands, holes of various sizes and shapes, or any other suitable shapes. In some embodiments, the shapes included in diffraction structure 103 may be implemented using metal or any dielectric material that has different refractive index than a material in which diffraction structure 103 is embedded, such as an oxide layer. In some embodiments, the number, size, spacing, and orientation of shapes included in diffraction structure 103 may be determined via simulation of sensor pixel 100. In some cases, the number, size, spacing, and orientation of the shapes included in diffraction structure 103 may be selected so as to cause the diffracted beams to avoid inactive regions, such, guard ring 108A, guard ring 108B, and other similar structures, within photodiode 101, and to direct the diffracted beams into avalanche initiation region 107 where the probability of generating avalanche current 116 is the highest.

Although diffraction structure 103 is depicted as including oxide 102, as described below, diffraction structure 103 when made with metal or any other suitable conductive material may be electrically coupled to a layer of epitaxial silicon coupled to side 115 of photodiode 101.

In some embodiments, optional planar reflector 106 is adjacent to side 115 and is configured to reflect a different photon of incoming light 109 back into avalanche initiation region 107. As described below, optional planar reflector 106 may be implemented using metal or any other suitable conductor, or any dielectric materials and may be fabricated as part of diffraction structure 103. In some embodiments, optional planar reflector 106 when made with metal, or any suitable conductive material, may be electrically connected to diffraction structure 103.

It is noted that side 114 and side 115 may be electrically connected by metal lines or traces, to a readout circuit that is configured to sense avalanche current 116 as well as quench photodiode 101 once avalanche breakdown has occurred.

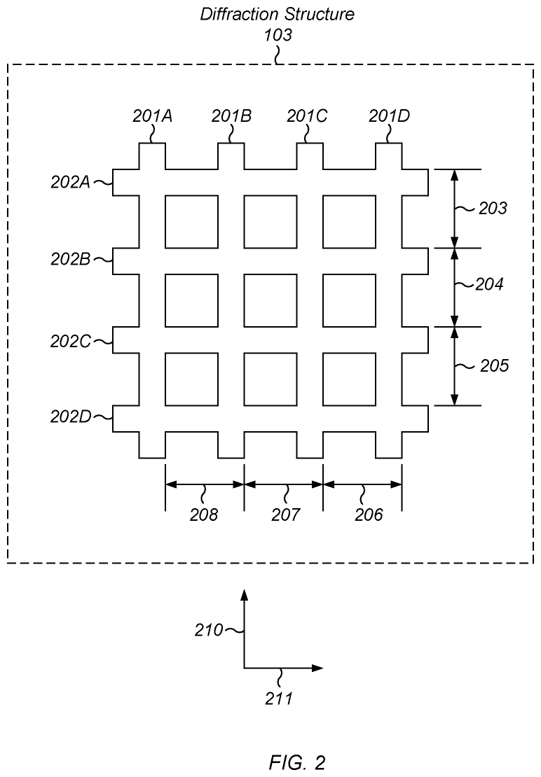

Turning to FIG. 2, a diagram of an embodiment of diffraction structure 103 is depicted. As illustrated, diffraction structure 103 includes lines 201A-D and lines 202A-D, which are connected together to form a grid. In various embodiments, lines 201A-D and 202A-D may be implemented using metal or any other suitable dielectric material that has a different index of refraction from a material in which lines 201A-D and 202A-D are embedded. Although the grid is depicted as being formed from 8 lines, in other embodiments, any suitable number of lines may be employed to form the grid.

Lines 202A-D are oriented in parallel with direction 211, while lines 201A-D are oriented in parallel with direction 210. In various embodiments, direction 210 is orthogonal to direction 211. It is noted that while the orientation of lines 201A-D and lines 202A-D within sensor pixel 100 may be arbitrary, lines 201A-D will be orthogonal to lines 202A-D. It is further noted that diffraction structure 103 can be aligned to arbitrary angles from the vertical sidewall (trench) of photodiode 101 as viewed from the top of photodiode 101. For example, an angle between diffraction structure 103 and the vertical sidewall of photodiode 101 may be between 0-degrees and 360-degrees.

In the present embodiment, lines 201A-D are equidistant from each other. In other words, distances 206-208 are equal to within the tolerance of the manufacturing process. In a similar fashion, lines 202A-D are equidistant from each other, with distances 203-205 being equal to within the tolerance of the manufacturing process. When the lines of diffraction structure 103 have the same width and spacing (referred to as “pitch”), diffraction structure 103 is referred to as being “periodic.” As described below, changes in either the widths lines 201A-D or lines 202A-D, or their corresponding spacing can result in diffraction structure 103 being “non-periodic.”

In various embodiments, lines 201A-D and lines 202A-D may be implemented using aluminum, copper, or any other suitable conductive material available in a semiconductor manufacturing process. Alternatively, or additionally, lines 201A-D and lines 202A-D may be implemented using any suitable dielectric material that has different refractive index than a material in which lines 201A-D and 202A-D are embedded. In some embodiments, such conductive materials may be combined with diffusion limiting barrier layers, for example, nickel, nichrome, tantalum, hafnium, niobium, zirconium, vanadium, and tungsten. In some cases, conductive ceramics, such as tantalum nitride, indium oxide, copper silicide, tungsten nitride, and titanium nitride, can also be used. It is noted that, in some cases, the number of lines used in direction 210 may not be the same as the number of lines used in direction 211. Moreover, the respective widths of lines 201A-D and lines 202A-D may be different. In various embodiments, the number of lines, the width of the lines, and the space between the lines may be based on simulations of sensor pixel 100 such that photons from as many incident angles as possible are reflected back into avalanche initiation region 107.

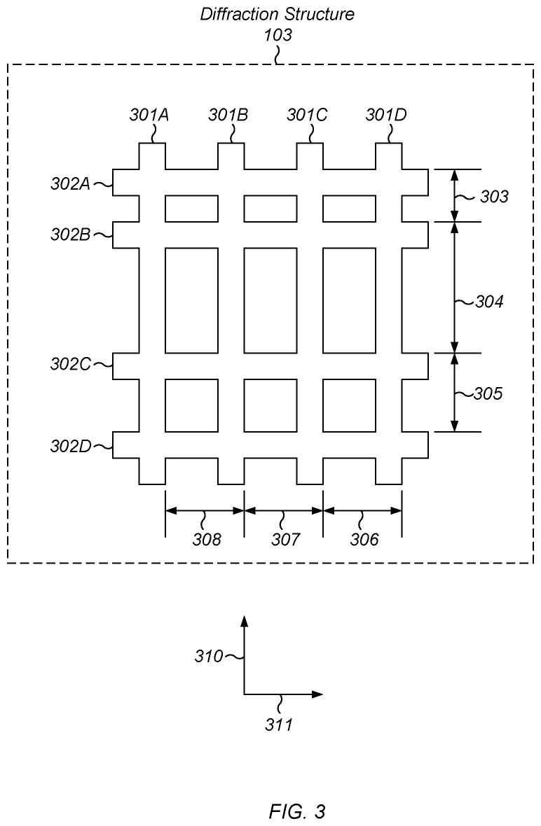

Turning to FIG. 3, a diagram of another embodiment of diffraction structure 103 is depicted. As illustrated, diffraction structure 103 includes lines 301A-D and lines 302A-D, which are connected together to form a grid. In various embodiments, lines 301A-D and 302A-D may be implemented using metal or any other suitable dielectric material that has a different index of refraction from a material in which lines 301A-D and 302A-D are embedded. Although the grid is depicted as being formed from 8 lines, in other embodiments, any suitable number of lines may be employed to form the grid.

Lines 302A-D are oriented in parallel with direction 311, while lines 301A-D are oriented in parallel with direction 310. In various embodiments, direction 310 is orthogonal to direction 311. It is noted that while the orientation of lines 301A-D and lines 302A-D within sensor pixel 100 may be arbitrary, lines 301A-D will be orthogonal to lines 302A-D. It is noted that diffraction structure 103, as depicted in FIG. 3, can be aligned to arbitrary angles from the vertical sidewall (trench) angle of photodiode 101 as viewed from the top of photodiode 101.

In the present embodiment, lines 301A-D are equidistant from each other. In other words, distances 306-308 are equal to within the tolerance of the manufacturing process. Lines 302A-D are, however, at different distances from each other. That is, distance 303 is different from distance 304, which is, in turn, different from distance 305. Since at least some of lines are separated by different spaces, the embodiments of diffraction structure 103 depicted in FIG. 3 is said to be “non-periodic.” Although lines 301A-D are depicted as being equidistant from each other, in other embodiments, lines 301A-D may be separated by different distances. In various embodiments, lines 301A-D and 302A-D can be “periodic” or “non-periodic.”

In various embodiments, lines 301A-D and lines 302A-D may be implemented using aluminum, copper, or any other suitable conductive material available in a semiconductor manufacturing process. Alternatively, or additionally, lines 301A-D and lines 302A-D may be implemented using any suitable dielectric material that has different refractive index than a material in which lines 301A-D and 302A-D are embedded. In some embodiments, such conductive materials may be combined with diffusion limiting barrier layers, for example, nickel, nichrome, tantalum, hafnium, niobium, zirconium, vanadium, and tungsten. In some cases, conductive ceramics, such as tantalum nitride, indium oxide, copper silicide, tungsten nitride, and titanium nitride, can also be used. It is noted that, in some cases, the number of lines used in direction 310 may not be the same as the number of lines used in direction 311. Moreover, the respective widths of lines 301A-D and lines 302A-D may be different. In various embodiments, the number of lines, the width of the lines, and the space between the lines may be based on simulations of sensor pixel 100 such that photons from as many incident angles as possible are reflected back into avalanche initiation region 107.

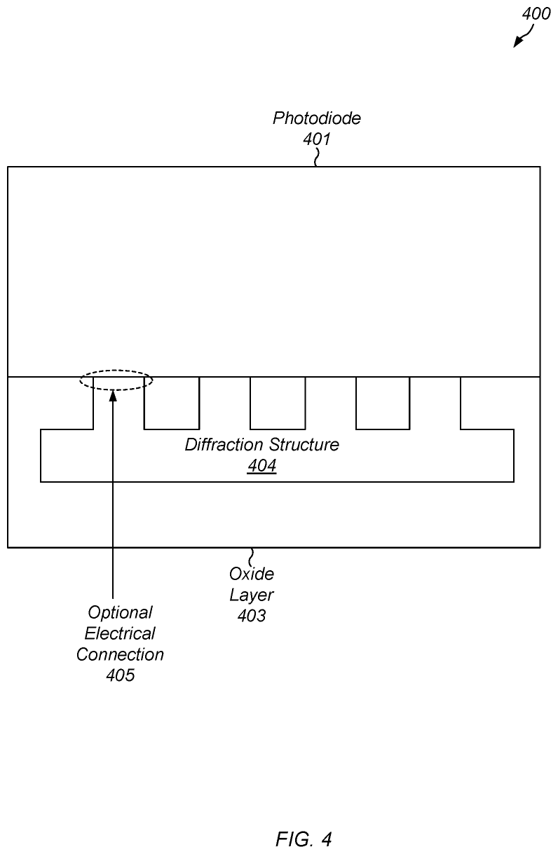

Turning to FIG. 4, a cross-section diagram of an embodiment of a sensor pixel is depicted without micro-lens 104. As illustrated, sensor pixel 400 includes silicon photodiode 401, and oxide layer 403, which includes diffraction structure 404. In various embodiments, sensor pixel 400 may correspond to sensor pixel 100 as depicted in FIG. 1. It is noted that some of the structure of sensor pixel 400 has been omitted for clarity.

In various embodiments, photodiode 401 may be implemented using an avalanche photodiode or any other suitable type of photodiode. In some embodiments, photodiode 401 may be fabricated with epitaxial silicon, which corresponds to a portion of an epitaxial wafer or “epi wafer.” In various embodiments, epitaxial silicon is fabricated by epitaxial growth (or “epitaxy”) on a silicon substrate.

Diffraction structure 404 may be fabricated through a combination of deposition, patterning, and etching steps. For example, oxide layer 403 may be deposited on the epitaxial silicon used to fabricate photodiode 401, and patterned and etched to allow a region for the shapes of diffraction structure 404 to be deposited. In various embodiments, diffraction structure 404 may include any suitable number of lines fabricated on any suitable number of layers. Diffraction structure 404 may be implemented using metal or any dielectric material that has different refractive index than oxide layer 403. In some embodiments, a planar reflector, such as optional planar reflector 106, may be fabricated along with diffraction structure 404.

In some embodiments, when diffraction structure 404 is implemented using metal, or any other suitable conductive material, diffraction structure 404 can be electrically connected to epitaxial silicon via optional electrical connection 405. In such cases, diffraction structure 404 may be at the same electric potential as metal contact to the epitaxial silicon of photodiode 401. For example, in some cases, both epitaxial silicon of photodiode 401 and diffraction structure 404 may both be at the same electric potential. In other embodiments, diffraction structure 404 may be electrically floating, or may be connected to any other suitable voltage level.

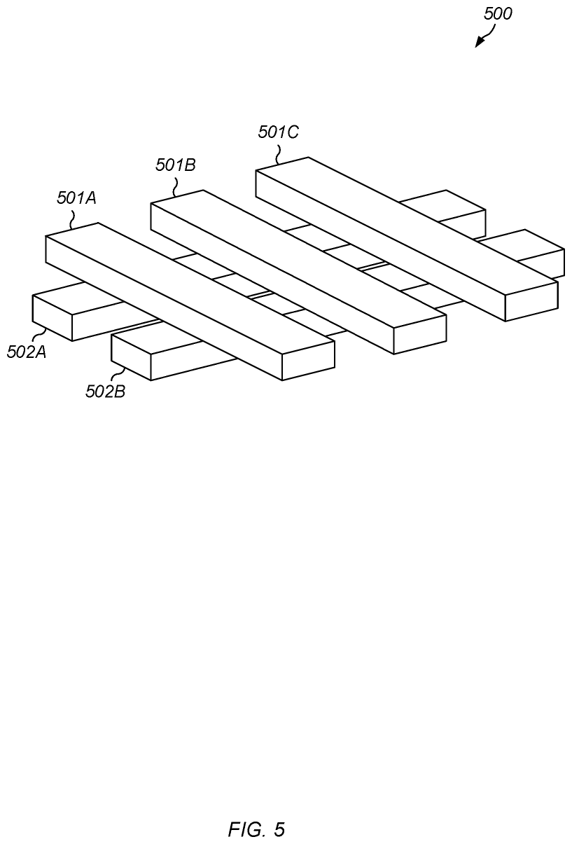

The diffraction structures depicted in FIGS. 2 and 3 are referred to as “2-D diffraction structures” as they are fabricated using a single layer of metal or any suitable dielectric material layer that has different refractive index than layers in which the diffraction structures are embedded. In some cases, in order to match the shape of avalanche initiation region 107, multiple layers of metal, or any suitable dielectric material, may be employed to form a “3-D diffraction structure.” A diagram of a multi-layer diffraction structure is depicted in FIG. 5. It is noted that a 3-D diffraction structure may be used in conjunction with a planar reflector, such as optional planar reflector 106.

As illustrated, lines 502A and 502B are fabricated on a first layer, while lines 501A-C are fabricated on a second layer. In various embodiments, lines 501A-C are oriented in a direction orthogonal to a direction in which lines 502A and 502B are oriented.

In some embodiments, lines 501A-C may be separated from lines 502A and 502B by silicon dioxide. In such cases, lines 501A-C may be connected to lines 502A and 502B using vias through the silicon dioxide. In other embodiments, there may not be an oxide present between lines 501A-C and lines 502A and 502B. In such cases, lines 501A-C may make electrical contact with lines 502A and 502B through direct contact.

Although only two lines are depicted on the first layer and three lines are depicted on the second layer, in other embodiments, any suitable number of lines may be employed on either layer. Moreover, although diffraction structure 500 is depicted as including lines on two layers, in other embodiments, more than two layers may be employed.

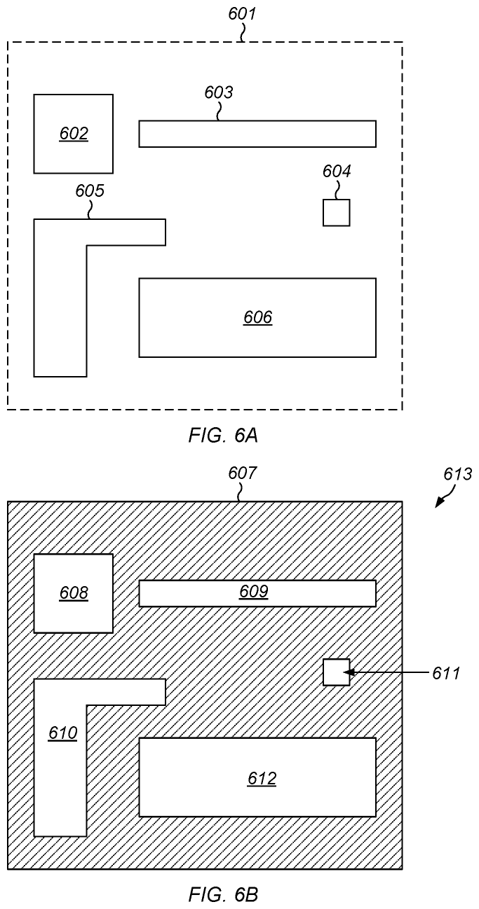

Turning to FIG. 6A, a block diagram of a diffraction structure including multiple islands is depicted. As illustrated, diffraction structure 601 includes shapes (also referred to as “islands”) 602-606, rather than a grid of overlapping lines. In various embodiments, shapes 602-606 may be implemented using metal or any suitable dielectric material that has a different index of refraction from a layer in which shapes 602-606 are embedded. In some embodiments, diffraction structure 601 may correspond to diffraction structure 103 as depicted in FIG. 1.

In various embodiments, shapes 602-606 are determined based on simulations of sensor pixel 100. In some cases, the respective sizes, positions, and orientations of shapes 602-606 are selected such that photons from as many incident angles as possible are reflected back into avalanche initiation region 107. It is noted that diffraction structure 601 may be used in conjunction with a planar reflector, such as optional planar reflector 106.

In various embodiments, shapes 602-606 may be implemented using aluminum, copper, or any other suitable conductive material available in a semiconductor manufacturing process. Alternatively, or additionally, shapes 602-606 may be implemented using any suitable dielectric material that has different refractive index than a layer in which shapes 602-606 are embedded. In some embodiments, such conductive materials may be combined with diffusion limiting barrier layers, for example, nickel, nichrome, tantalum, hafnium, niobium, zirconium, vanadium, and tungsten. In some cases, conductive ceramics, such as tantalum nitride, indium oxide, copper silicide, tungsten nitride, and titanium nitride, may also be used. Although diffraction structure 601 is depicted as including 5 shapes, in other embodiments, any suitable number of shapes in any suitable arrangement may be employed.

Turning to FIG. 6B, a block diagram of a diffraction structure including multiple voids is in a metal or dielectric layer is depicted. As illustrated, diffraction structure 613 includes plate 607, which includes voids (or “holes”) 608-612. In various embodiments, plate 607 may be implemented using metal or any suitable dielectric material. In some embodiments, diffraction structure 613 may correspond to diffraction structure 103 as depicted in FIG. 1.

In various embodiments, voids 608-612 are determined based on simulations of sensor pixel 100. In some cases, the respective shapes, sizes, positions, and orientations of voids 608-612 are selected such that photons from as many incident angles as possible are reflected back into avalanche initiation region 107. It is noted that diffraction structure 613 may be used in conjunction with a planar reflector, such as optional planar reflector 106.

In various embodiments, plate 607 may be implemented using aluminum, copper, or any other suitable conductive material available in a semiconductor manufacturing process. Alternatively, or additionally, plate 607 may be implemented using any suitable dielectric material that has different refractive index than a layer in which plate 607 is embedded. In some embodiments, such conductive materials may be combined with diffusion limiting barrier layers, for example, nickel, nichrome, tantalum, hafnium, niobium, zirconium, vanadium, and tungsten. In some cases, conductive ceramics, such as tantalum nitride, indium oxide, copper silicide, tungsten nitride, and titanium nitride, can also be used. Although diffraction structure 613 is depicted as including 5 voids in plate 607, in other embodiments, any suitable number of voids in plate 607 arranged in any suitable fashion may be employed.

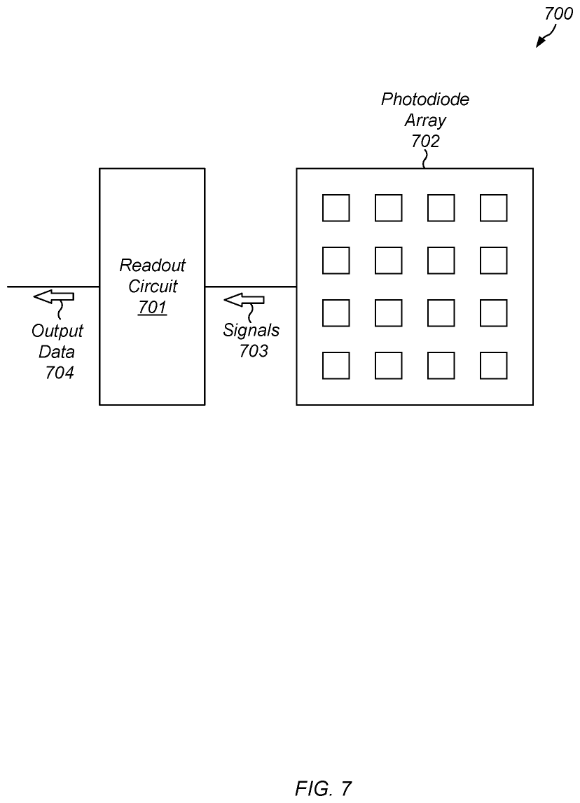

Turning to FIG. 7, a block diagram of an image sensor is depicted. As illustrated, image sensor 700 includes readout circuit 701 and photodiode array 702 which includes multiple sensor pixels, such as sensor pixel 100 as depicted in FIG. 1.

Photodiode array 702 is configured to generate signals 703 based on an exposure of the sensor pixels to electromagnetic radiation. In various embodiments, the electromagnetic radiation can be of any suitable frequency (or wavelength) based on the construction of the sensor pixels in photodiode array 702. For example, photodiode array 702 may employ sensor pixels that are sensitive to infrared light. Alternatively, photodiode array 702 may employ sensor pixels that are sensitive to visible light. In some embodiments, photodiode array 702 may include a variety of sensor pixels that are sensitive to respective frequencies (or wavelength) of electromagnetic radiation. In various embodiments, signals 703 may correspond to respective currents from the sensor pixels included in photodiode array 702.

In some embodiments, the sensor pixels included in photodiode array 702 may be fabricated on a common substrate. In other embodiments, photodiode array 702 may include different groups of sensor pixels fabricated on corresponding substrates. Although only 16 sensor pixels are depicted in the embodiment of photodiode array 702, in other embodiments, any suitable number of sensor pixels may be included in photodiode array 702.

Readout circuit 701 is configured to generate output data 704 using signals 703. In some cases, readout circuit 701 may convert respective currents from the sensor pixels in photodiode array 702 into corresponding voltages. In various embodiments, readout circuit 701 may perform multiple analog-to-digital conversion operations to translate signals 703 into multiple bits included in output data 704.

In some cases, readout circuit 701 may be configured to provide control signals and voltages for the sensor pixels included in photodiode array 702. In various embodiments, readout circuit 701 may be configured to maintain the sensor pixels included in photodiode array 702 under reverse bias in order to promote avalanche breakdown. Additionally, readout circuit 701 may be configured to quench the sensor pixels included in photodiode array 702 after avalanche breakdown has occurred in order to return the sensor pixels to a state where further light sensing can be performed.

In various embodiments, readout circuit 701 may be implemented using one or more analog-to-digital converter circuits, operational transconductance amplifier circuits, microcontroller circuits, and the like.

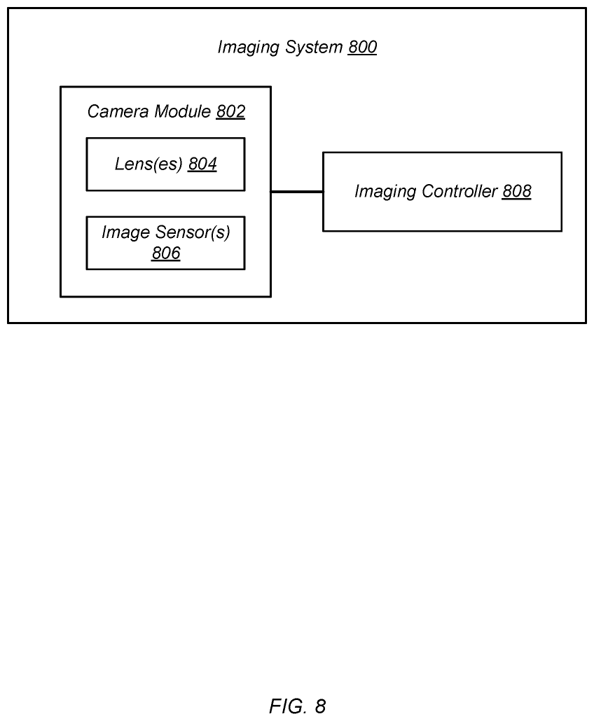

Turning to FIG. 8, a block diagram of an embodiment of an imaging system is depicted. In various embodiments, imaging system 800 may be a portable electronic device such as a camera, a cellular telephone, a tablet computer, a webcam, a video camera, a video surveillance system, or a video gaming system with imaging capabilities. In other embodiments, imaging system 800 may be an automotive imaging system. As illustrated, imaging system 800 includes camera module 802 that may be used to convert incoming light into digital image data. Camera module 802 may include one or more lenses 804 and one or more corresponding image sensors 806. In various embodiments, one or more of image sensors 806 may correspond to image sensor 700 as depicted in FIG. 7. Lenses 804 may be implemented using either fixed and/or adjustable lenses. When an image capture operation is performed, light from a scene may be focused onto image sensor 806 by lenses 804. Image sensor 806 may include circuitry for converting analog pixel data into corresponding digital image data to be provided to imaging controller 808. In some embodiments, camera module 802 may include an array of lenses 804 and an array of corresponding image sensors 806.

Imaging controller 808 may include one or more integrated circuits. The integrated circuits may include image processing circuits, microprocessors, and storage devices, such as random-access memory circuits, non-volatile memory circuits, and the like. Imaging controller 808 may be implemented using components that are separate from camera module 802 and/or that form part of camera module 802, for example, circuits that form part of image sensors 806. Digital image data captured by camera module 802 may be processed and stored using imaging controller 808. Processed image data may, if desired, be provided to external equipment, such as a computer, external display, or other device, using wired and/or wireless communication paths coupled to imaging controller 808.

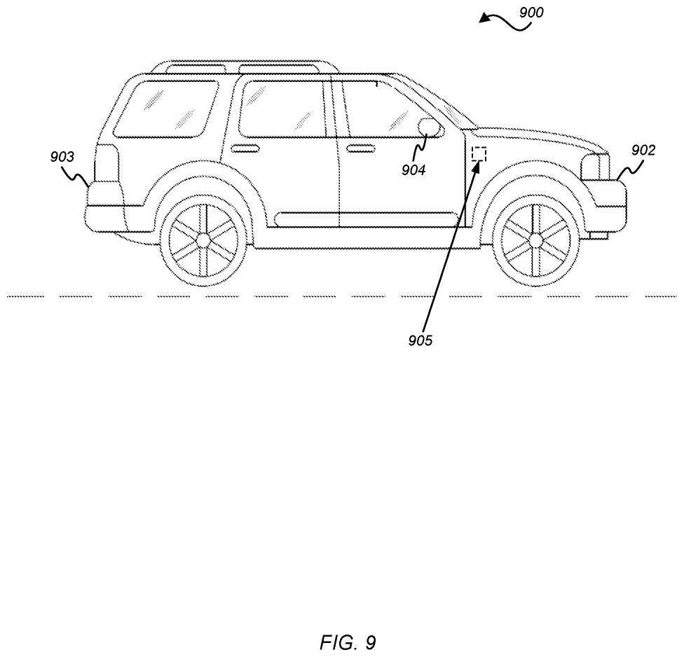

Turning to FIG. 9, a block diagram of an embodiment of a vehicle with an imaging system is depicted. As illustrated, vehicle 900 includes forward-looking camera module 902, backward-looking camera module 903, side-looking camera module 904, and imaging controller 905. In various embodiments, forward-looking camera module 902, backward-looking camera module 903, and side-looking camera module 904 may correspond to various instances of camera module 802, and imaging controller 905 may correspond to imaging controller 808 as depicted in FIG. 8.

Forward-looking camera module 902 is configured to capture images of scenes in front of vehicle 900. Such images can be used for any suitable purpose, such as lane-keeping assist, collision warning systems, distance-pacing cruise-control systems, autonomous driving systems, and proximity detection, for example.

Backward-looking camera module 903 is configured to capture images of scenes behind vehicle 900. Such images can be used for any suitable purpose, such as collision warning systems, reverse direction video, autonomous driving systems, proximity detection, monitoring position of overtaking vehicles, and backing up, for example.

Side-looking camera module 904 is configured to capture images of scenes beside vehicle 900. Such images can be used for any suitable purpose, such as blind-spot monitoring, collision warning systems, autonomous driving systems, monitoring position of overtaking vehicles, lane-change detection, and proximity detection, for example.

Vehicle 900 is illustratively shown as a passenger vehicle, but the components of the imaging system, for example, forward-looking camera module 902, may be used with other types of vehicles, including commercial vehicles, on-road vehicles, and off-road vehicles. Commercial vehicles may include busses and tractor-trailer vehicles. Off-road vehicles may include tractors and crop harvesting equipment.

Imaging controller 905 is configured to process image data from forward-looking camera module 902, backward-looking camera module 903, and side-looking camera module 904 to generate corresponding images. Such images may be relayed to one or more processor circuits (not shown) included in vehicle 900 for further processing, such as image recognition and the like. In various embodiments, the one or more processor circuits may generate warning messages, activate brakes, adjust the speed of vehicle 900, and the like, based on the image data received from imaging controller 905. Although imaging controller 905 is depicted as being located in the engine compartment of vehicle 900, in other embodiments, imaging controller 905 may be located in any suitable location within vehicle 900.

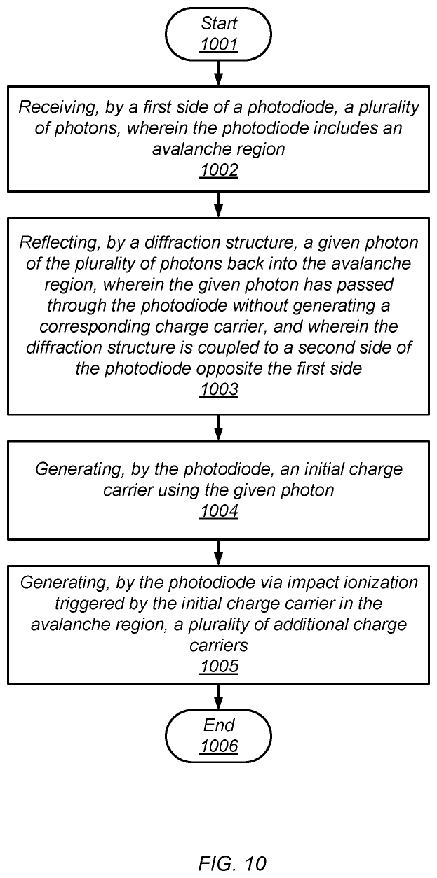

Turning to FIG. 10, a flow diagram depicting an embodiment for operating a sensor pixel is illustrated. The method, which may be applied to various sensor pixels, for example, sensor pixel 100 as depicted in FIG. 1, begins in block 1001.

The method includes receiving, by a first side of a photodiode, a plurality of photons (block 1002). In various embodiments, the photodiode includes an avalanche region. In some cases, the first side of the photodiode is coupled to a micro-lens.

The method also includes reflecting, by a diffraction structure, a given photon of the plurality of photons back into the avalanche region (block 1003). In various embodiments, the given photo has passed through the photodiode without generating a corresponding charge carrier. In some cases, the diffraction structure includes a plurality of first lines that are coupled to a second side of the photodiode opposite to the first side. In various embodiments, the plurality of first lines may be implemented using metal or any suitable dielectric material that has different refractive index than a layer in which the diffraction structure is embedded layer.

In some embodiments, the method may further include reflecting, by a planar reflector, a different photon of the plurality of photons back into the avalanche region. In such cases, the planar reflector may be coupled to the second side of the photodiode. In other embodiments, the second side of the photodiode is coupled to a layer of epitaxial silicon, and the diffraction structure is electrically coupled to the epitaxial silicon.

In various embodiments, the plurality of first lines is equidistantly spaced, while, in other embodiments, a first space between a first line of the plurality of first lines and a second line of the plurality of first lines is different than a second space between a third line of the plurality of first lines and a fourth line of the plurality of first lines.

In some cases, the plurality of first lines is fabricated on a first layer, and the diffraction structure further includes a plurality of second lines fabricated on a second layer different than the first layer. In other embodiments, the plurality of first lines is oriented parallel to a first direction, and where the plurality of second lines are oriented parallel to a second direction that is orthogonal to a first direction.

The method further includes generating, by the photodiode, an initial charge carrier using the given photon (block 1004). In various embodiments, generating the initial charge carrier includes generating an electron-hole pair by absorption of the given photon at a PN junction of the photodiode.

The method also includes generating, by the photodiode via impact ionization triggered by the initial charge carrier in the avalanche region, a plurality of additional charge carriers (block 1005). In various embodiments, the method may further include generating, by the photodiode, an avalanche current using the plurality of additional charge carriers. The method concludes in block 1006.

The present disclosure includes references to “an embodiment” or groups of “embodiments.” As used herein, embodiments are different implementations of instances of the disclosed concepts. References to “an embodiment,” “some embodiments,” and the like do not necessarily refer to the same embodiment. Many embodiments are possible and contemplated, including those specifically disclosed as well as modifications or alternatives that fall within the spirit or scope of the disclosure.

The above disclosure is meant to illustrate some of the principles and various embodiments of the disclosed concepts. Numerous variations and modifications will become apparent to those skilled in the art once the above disclosure is fully appreciated. It is intended that the following claims be interpreted to embrace all such variations and modifications.

What is claimed is:

1. An apparatus, comprising:
a photodiode that includes an avalanche region, wherein the photodiode is configured to:
generate an initial charge carrier using a particular photon of a plurality of photons received on a first side of the photodiode; and
generate an avalanche current in response to a generation, by the initial charge carrier via impact ionization, of a plurality of additional charge carriers in the avalanche region; and
a diffraction structure adjacent to a second side of the photodiode opposite the first side, wherein the diffraction structure includes a plurality of first metal or dielectric lines, and wherein the diffraction structure is configured to reflect at least one of the plurality of photons back into the avalanche region.

2. The apparatus of claim 1, further comprising a planar reflector adjacent to the second side of the photodiode, wherein the planar reflector is configured to reflect a different photon of the plurality of photons back into the avalanche region.

3. The apparatus of claim 1, wherein the plurality of first metal or dielectric lines are equidistantly spaced.

4. The apparatus of claim 1, wherein a first space between a line of the plurality of first metal or dielectric lines and a second line of the plurality of first metal or dielectric lines is different than a second space between a third line of the plurality of first metal or dielectric lines and a fourth line of the plurality of first metal or dielectric lines.

5. The apparatus of claim 1, wherein the plurality of first metal or dielectric lines are fabricated on a first layer, and wherein the diffraction structure further includes a plurality of second metal or dielectric lines fabricated on a second layer different than the first layer.

6. The apparatus of claim 1, further comprising a layer of epitaxial silicon coupled to the second side of the photodiode, wherein the diffraction structure is electrically coupled to the epitaxial silicon.

7. A method, comprising:
receiving, by a first side of a photodiode, a plurality of photons, wherein the photodiode includes an avalanche region;
reflecting, by a diffraction structure, a given photon of the plurality of photons back into the avalanche region, wherein the given photon has passed through the photodiode without generating a corresponding charge carrier, wherein the diffraction structure includes a plurality of first metal or dielectric lines and is coupled to a second side of the photodiode opposite the first side;
generating, by the photodiode, an initial charge carrier using the given photon; and
generating, by the photodiode via impact ionization triggered by the initial charge carrier in the avalanche region, a plurality of additional charge carriers.

8. The method of claim 7, further comprising, reflecting, by a planar reflector, a different photon of the plurality of photons back into the avalanche region, wherein the planar reflector is coupled to the second side of the photodiode.

9. The method of claim 7, wherein the plurality of first metal or dielectric lines are equidistantly spaced.

10. The method of claim 7, wherein a first space between a first line of the plurality of first metal or dielectric lines and a second line of the plurality of first metal or dielectric lines is different than a second space between a third line of the plurality of first metal or dielectric lines and a fourth line of the plurality of first metal or dielectric lines.

11. The method of claim 7, wherein the plurality of first metal or dielectric lines are fabricated on a first layer, and wherein the diffraction structure further includes a plurality of second metal or dielectric lines fabricated on a second layer different than the first layer.

12. The method of claim 11, wherein an angle between a vertical sidewall of photodiode and the plurality of first metal or dielectric lines is between 0-degrees and 360-degrees.

13. The method of claim 7, wherein the second side of the photodiode is coupled to a layer of epitaxial silicon, and wherein the diffraction structure is electrically coupled to the epitaxial silicon.

14. An apparatus, comprising:
a camera module that includes a plurality of image sensors that includes a given image sensor that includes a readout circuit and a plurality of sensor pixels including a given sensor pixel that includes a photodiode and a diffraction structure, wherein the camera module is configured to generate image data based on incoming light; and
an imaging controller configured to process the image data.

15. The apparatus of claim 14, wherein the photodiode includes an avalanche region and is configured to receive a portion of the incoming light on a first side, wherein the diffraction structure coupled to a second side of the photodiode opposite the first side, wherein the diffraction structure includes a plurality of first lines, wherein the diffraction structure is configured to reflect at least one photon of the portion of the incoming light back into the avalanche region, and wherein the plurality of first lines are fabricated from metal or dielectric material.

16. The apparatus of claim 15, wherein the given sensor pixel further includes a planar reflector coupled to the second side of the photodiode, wherein the planar reflector is configured to reflect a different photon of the portion of the incoming light back into the avalanche region, and wherein the planar reflector is fabricated from metal or dielectric material.

17. The apparatus of claim 15, wherein the plurality of first lines are equidistantly spaced.

18. The apparatus of claim 15, wherein a first space between a first line of the plurality of first lines and a second line of the plurality of first lines is different than a second space between a third line of the plurality of first lines and a fourth line of the plurality of first lines.

19. The apparatus of claim 14, wherein the diffraction structure includes a plurality of shapes of metal or dielectric material.

20. The apparatus of claim 14, wherein the diffraction structure includes a plate that includes one or more voids, wherein the plate is fabricated from metal or dielectric material.
